(19) United States
(12) Patent Application Publication
(10) Pub. No.: US 2025/0248150 A1
(43) Pub. Date: Jul. 31, 2025

(54) SENSOR PACKAGE STRUCTURE

(71) Applicant: TONG HSING ELECTRONIC INDUSTRIES, LTD., Taipei City (TW)

(72) Inventors: YU-HSIANG LIU, Taipei City (TW); LI-CHUN HUNG, Hsin-Chu County (TW)

(21) Appl. No.: 18/626,274

(22) Filed: Apr. 3, 2024

(30) Foreign Application Priority Data
Jan. 26, 2024 (TW) 113103048

(51) Int. Cl. H01L 27/146; H01L 23/00

(52) U.S. Cl. CPC H10F 39/804; H01L 24/48; H10F 39/811; H01L 24/32; H01L 24/73; H01L 2224/32225; H01L 2224/48227; H01L 2224/73265

(57) ABSTRACT

A sensor package structure includes a substrate, a sensor chip disposed on the substrate, a ring-shaped supporting layer disposed on the sensor chip, and a light-permeable sheet that is disposed on the ring-shaped supporting layer. The light-permeable sheet has an outer surface and an inner surface that is opposite to the outer surface, and has a ring-shaped distribution groove that is opposite to the outer surface and that surrounds the inner surface. A top portion of the ring-shaped supporting layer is arranged in the ring-shaped distribution groove and abuts against a ring-shaped slanting wall of the ring-shaped distribution groove, so that a height of an inner supporting wall of the ring-shaped distribution groove is within a range from 120% to 150% of a height of an outer supporting wall of the ring-shaped distribution groove.

### CROSS-REFERENCE TO RELATED PATENT APPLICATION

This application claims the benefit of priority to Taiwan Patent Application No. 113103048, filed on Jan. 26, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a package structure, and more particularly to a sensor package structure.

### BACKGROUND OF THE DISCLOSURE

A conventional sensor package structure includes a glass board, a sensor chip, and an adhesive that is adhered to and arranged between the glass board and the sensor chip. Since air inside the conventional sensor package structure would expand when heated, stress concentration can occur at an inner side of the adhesive and cause cracks to form thereon.

### SUMMARY OF THE DISCLOSURE

In response to the above-referenced technical inadequacies, the present disclosure provides a sensor package structure for effectively improving on the issues associated with conventional sensor package structures.

In order to solve the above-mentioned problems, one of the technical aspects adopted by the present disclosure is to provide a sensor package structure, which includes a substrate, a sensor chip, a ring-shaped supporting layer, and a light-permeable sheet. The substrate has a first surface and a second surface that is opposite to the first surface. The sensor chip is disposed on the first surface of the substrate and is electrically coupled to the substrate. Moreover, a top surface of the sensor chip has a sensing region and a carrying region that is arranged outside of the sensing region. The ring-shaped supporting layer is disposed on the carrying region and surrounds the sensing region. The light-permeable sheet is disposed on the ring-shaped supporting layer. The light-permeable sheet, an inner supporting wall of the ring-shaped supporting layer, and the top surface of the sensor chip jointly define an enclosed space. The light-permeable sheet has an outer surface, an inner surface, and a ring-shaped distribution groove. The inner surface is opposite to the outer surface and faces toward the sensing region. The sensing region is located in a projection region defined by orthogonally projecting the inner surface onto the top surface. The ring-shaped distribution groove is arranged opposite to the outer surface and surrounds the inner surface. The ring-shaped distribution groove has a ring-shaped slanting wall and an inner side wall that is connected in-between the inner surface and an inner edge of the ring-shaped slanting wall. Moreover, a top portion of the ring-shaped supporting layer is disposed in the ring-shaped distribution groove and is connected to the ring-shaped slanting wall, such that a height of the inner supporting wall is within a range from 120% to 150% of a height of an outer supporting wall of the ring-shaped supporting layer.

Therefore, the light-permeable sheet of the sensor package structure provided by the present disclosure is formed with the ring-shaped slanting wall that is structurally cooperated with the ring-shaped supporting layer, so that the ring-shaped supporting layer can be shaped to effectively improve a stress concentration in the inner supporting wall, thereby preventing a crack from occurring at the inner supporting wall.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view of a sensor package structure according to a first embodiment of the present disclosure;

FIG. 2 is a schematic exploded view of FIG. 1;

FIG. 3 is a schematic top view of FIG. 1;

FIG. 4 is a schematic cross-sectional view taken along line IV-IV of FIG. 1;

FIG. 5 is a schematic enlarged view of part V of FIG. 4;

FIG. 6 is a schematic cross-sectional view of the sensor package structure according to a second embodiment of the present disclosure;

FIG. 7 is a schematic enlarged view of part VII of FIG. 6; and

FIG. 8 is a schematic cross-sectional view of the sensor package structure according to a third embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

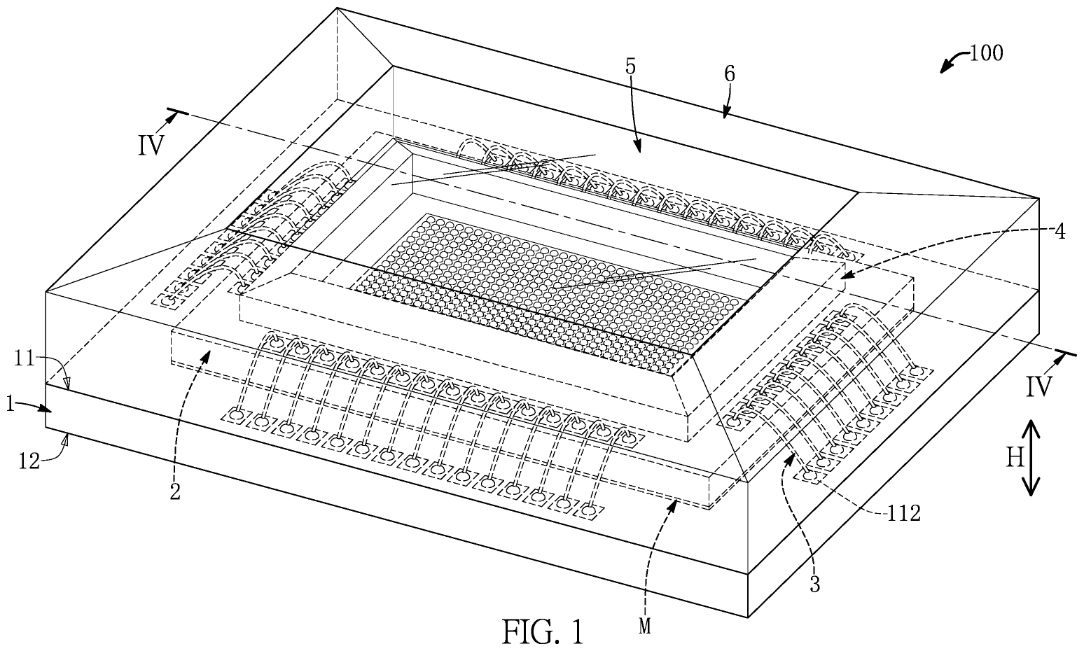

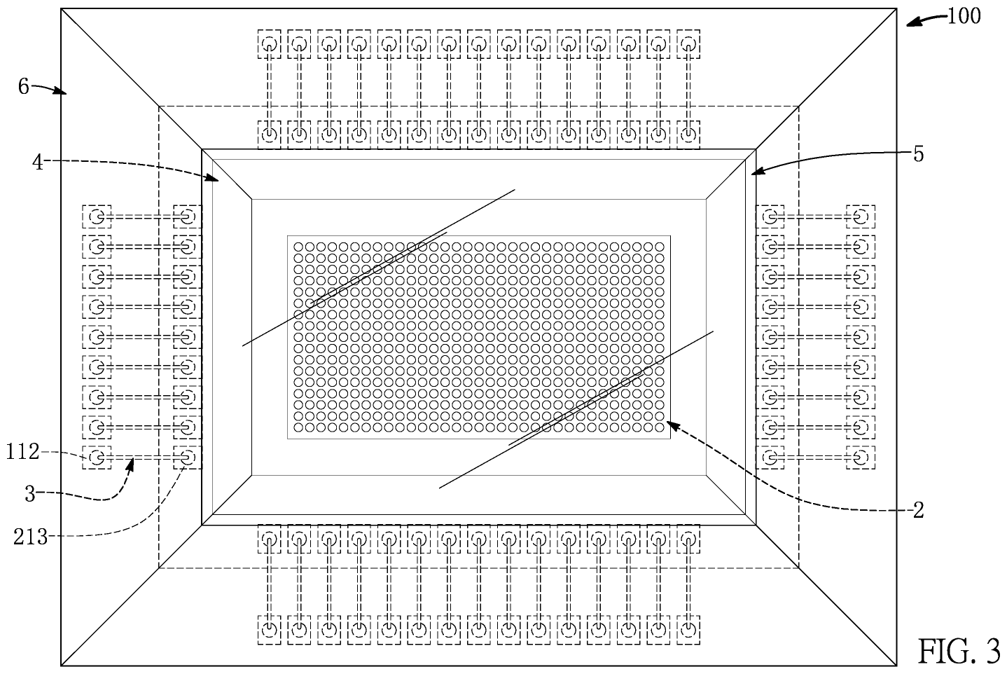

Referring to FIG. 1 to FIG. 5, a first embodiment of the present disclosure is provided. As shown in FIG. 1 to FIG. 3, the present embodiment provides a sensor package structure 100. In other words, any package structure not encapsulating a sensor chip therein has a structural design different from that of the sensor package structure 100 of the present embodiment.

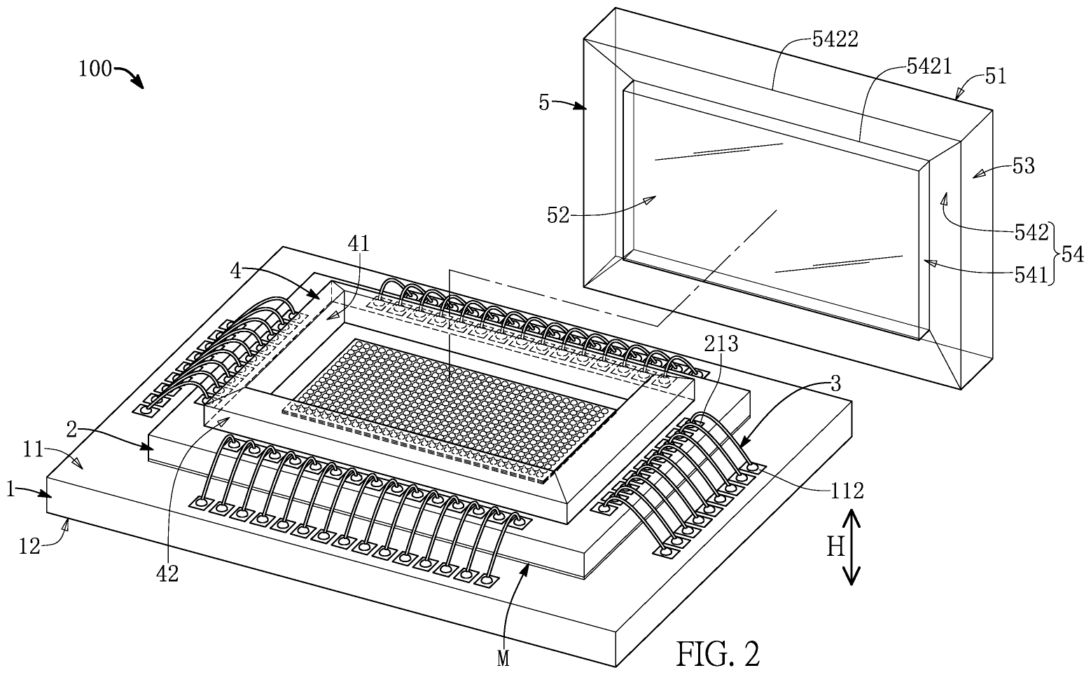

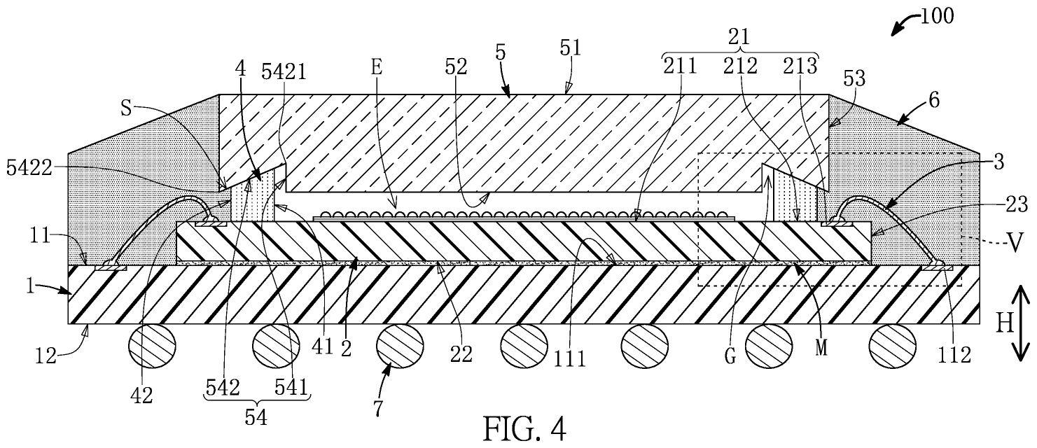

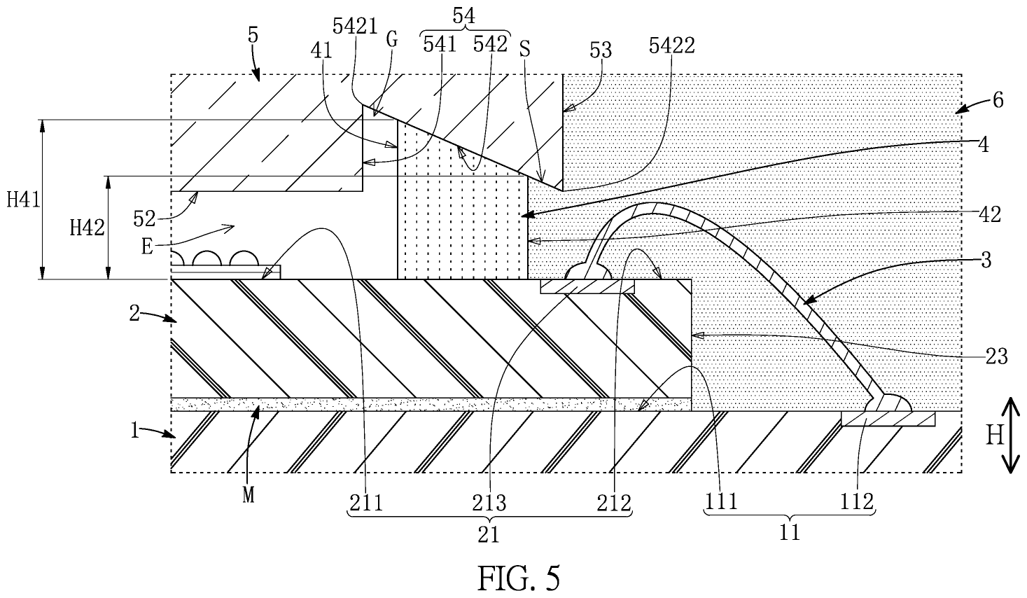

As shown in FIG. 2, FIG. 4, and FIG. 5, the sensor package structure 100 includes a substrate 1, a sensor chip 2 disposed on and electrically coupled to the substrate 1, a plurality of metal wires 3 electrically coupled to the sensor chip 2 and the substrate 1, a ring-shaped supporting layer 4 disposed on the sensor chip 2, a light-permeable layer 5 disposed on the ring-shaped supporting layer 4, and an encapsulant 6 that is formed on the substrate 1.

The sensor package structure 100 in the present embodiment includes the above components, but can be adjusted or changed according to design requirements. For example, in other embodiments of the present disclosure not shown in the drawings, the sensor package structure 100 can be provided without the metal wires 3, and the sensor chip 2 is fixed onto and electrically coupled to the substrate 1 in a flip-chip manner; or, the encapsulant 6 of the sensor package structure 100 can be omitted or can be replaced by other components. The structure and connection relationship of each component of the sensor package structure 100 are recited in the following description.

The substrate 1 of the present embodiment has a square shape or a rectangular shape, but the present disclosure is not limited thereto. The substrate 1 has a first surface 11 and a second surface 12 that is opposite to the first surface 11. The first surface 11 of the substrate 1 includes a chip-bonding region 111 arranged approximately on a center portion thereof, and the substrate 1 includes a plurality of bonding pads 112 that are disposed on the first surface 11 and are arranged outside of the chip-bonding region 111 (or the sensor chip 2). The bonding pads 112 in the present embodiment are in an annular arrangement, but the present disclosure is not limited thereto. For example, in other embodiments of the present disclosure not shown in the drawings, the bonding pads 112 can be arranged in two rows respectively at two opposite sides of the chip-bonding region 111.

In addition, the substrate 1 can be further provided with a plurality of solder balls 7 disposed on the second surface 12 thereof. The substrate 1 can be soldered onto an electronic component (not shown in the drawings) through the solder balls 7, thereby electrically connecting the sensor package structure 100 to the electronic component.

The sensor chip 2 in the present embodiment is an image sensing chip, but the present disclosure is not limited thereto. The sensor chip 2 is fixed onto the first surface 11 of the substrate 1 (e.g., the chip-bonding region 111) through a bottom surface 22 thereof. In other words, the sensor chip 2 is arranged to be surrounded on the inside of the bonding pads 112. It should be noted that the sensor package structure 100 in the present embodiment includes an adhesive M (e.g., a conductive glue) disposed on the chip-bonding region 111, and the sensor chip 2 is fixed onto the chip-bonding region 111 through the adhesive M (e.g., the bottom surface 22 of the sensor chip 2 and the chip-bonding region 111 being fixed and adhered to each other through the adhesive M), but the present disclosure is not limited thereto. For example, in other embodiments of the present disclosure not shown in the drawings, the adhesive M can be omitted or can be replaced by other components.

Moreover, a top surface 21 of the sensor chip 2 has a sensing region 211 and a carrying region 212 that has an annular shape surrounding the sensing region 211. It should be noted that the sensor package structure 100 in the present embodiment is provided for packaging the senor chip 2 of a smaller size through a structural cooperation thereof. For example, a distance between the sensing region 211 and a lateral surface 23 of the sensor chip 2 is less than 1 mm, but the present disclosure is not limited thereto.

Specifically, the sensor chip 2 in the present embodiment includes a plurality of connection pads 213 arranged on the carrying region 212. Moreover, the number and positions of the connection pads 213 of the sensor chip 2 in the present embodiment correspond to those of the bonding pads 112 of the substrate 1. In other words, the connection pads 213 are in an annular arrangement, and a quantity of the connection pads 213 is equal to a quantity of the bonding pads 112.

Each of the metal wires 3 has two ends, one of the two ends of each of the metal wires 3 is connected to one of the bonding pads 112, and another one of the two ends of each of the metal wires 3 is connected to one of the connection pads 213, so that the substrate 1 and the sensor chip 2 can be electrically connected to each other through the metal wires 3. Any one of the metal wires 3 can be configured in a normal bonding manner or a reverse bonding manner according to design requirements, and the present disclosure is not limited thereto.

The ring-shaped supporting layer 4 in the present embodiment is an opaque layer. The ring-shaped supporting layer 4 is disposed on the carrying region 212 of the sensor chip 2 and surrounds the sensing region 211 of the sensor chip 2. Specifically, the connection pads 213 are arranged outside of the ring-shaped supporting layer 4, and the metal wires 3 and the connection pads 213 are embedded in the encapsulant 6.

The light-permeable sheet 5 in the present embodiment is a transparent and flat glass board, but the present disclosure is not limited thereto. The light-permeable sheet 5 is disposed on the ring-shaped supporting layer 4. The light-permeable layer 5, an inner supporting wall 41 of the ring-shaped supporting layer 4, and the top surface 21 of the sensor chip 2 jointly and surroundingly define an enclosed space E.

Specifically, the light-permeable sheet 5 in the present embodiment has an outer surface 51, an inner surface 52, a ring-shaped distribution groove 54, and a surrounding lateral surface 53 that is connected to the outer surface 51. The inner surface 52 and the ring-shaped distribution groove 54 are arranged opposite to the outer surface 51. In the present embodiment, the outer surface 51 and the inner surface 52 are substantially parallel to each other, the inner surface 52 faces toward the sensing region 211, and the sensing region 211 is located in a projection region defined by orthogonally projecting the inner surface 52 onto the top surface 21 of the sensor chip 2.

Each of the outer surface 51, the inner surface 52, and the surrounding lateral surface 53 in the present embodiment is flat, but can be adjusted or changed according to design requirements. Moreover, the ring-shaped distribution groove 54 in the present embodiment can be formed by processing the light-permeable sheet 5 in any manner (e.g., a blade cutting manner, a laser cutting manner, and/or an etching manner), and the present disclosure is not limited thereto.

The ring-shaped distribution groove 54 surrounds the inner surface 52, and a depth of the ring-shaped distribution groove 54 is preferably not greater than 50% of a thickness of the light-permeable sheet 5. The ring-shaped distribution groove 54 has a ring-shaped slanting wall 542 and an inner side wall 541 that is connected in-between the inner surface 52 and an inner edge 5421 of the ring-shaped slanting wall 542. The ring-shaped slanting wall 542 in the present embodiment is formed with flat surfaces, but the present disclosure is not limited thereto. For example, in other embodiments of the present disclosure not shown in the drawings, the ring-shaped slanting wall 542 can be formed with convex surfaces or concave surfaces according to design requirements.

Moreover, the surrounding lateral surface 53 is connected in-between the outer surface 51 and an outer edge 5422 of the ring-shaped slanting wall 542, and the outer edge 5422 of the ring-shaped slanting wall 542 is coplanar with the inner surface 52 of the light-permeable sheet 5. In order to clearly describe the present embodiment, a direction perpendicular to the inner surface 52 in the present embodiment is defined as a thickness direction H. The inner side wall 541 of the ring-shaped distribution groove 54 and the thickness direction H have a first angle therebetween, and the ring-shaped slanting wall 542 and the thickness direction H have a second angle therebetween that is greater than the first angle. In the present embodiment, the first angle is preferably within a range from 0 degrees to 10 degrees, and the second angle is preferably within a range from 30 degrees to 70 degrees, but the present disclosure is not limited thereto.

In summary, the light-permeable sheet 5 is located above the sensor chip 2 through the cooperation between the ring-shaped distribution groove 54 and the ring-shaped supporting layer 4. In other words, the ring-shaped supporting layer 4 in the present embodiment is sandwiched between the ring-shaped slanting wall 542 of the light-permeable sheet 5 and the carrying region 212 of the sensor chip 2, and the sensing region 211 and the inner side wall 541 of the ring-shaped distribution groove 54 are arranged in the enclosed space E.

Specifically, a top portion of the ring-shaped supporting layer 4 is disposed in the ring-shaped distribution groove 54 and is connected to the ring-shaped slanting wall 542, such that a height H41 of the inner supporting wall 41 along the height direction H is within a range from 120% to 150% of a height H42 of an outer supporting wall 42 of the ring-shaped supporting layer 4 along the height direction H. In addition, the height H41 of the inner supporting wall 41 is preferably within a range from 130% to 140% of the height H42 of the outer supporting wall 42, but the present disclosure is not limited thereto.

Accordingly, the light-permeable sheet 5 of the sensor package structure 100 in the present embodiment is formed with the ring-shaped slanting wall 542 that is cooperated with the ring-shaped supporting layer 4, so that the ring-shaped supporting layer 4 can be shaped to effectively improve a stress concentration in the inner supporting wall 41, thereby preventing a crack from occurring at the inner supporting wall 41.

For example, in a simulation test under an environment temperature of 260° C., the adhesive of the conventional sensor package structure has a same height and the glass board of the conventional sensor package structure does not have the ring-shaped slanting wall 542, the inner side of the adhesive in the conventional sensor package structure has a first maximum stress value (e.g., 6.47 MPa), and the inner supporting wall 41 in the sensor package structure 100 of the present embodiment has a second maximum stress value (e.g., 5.48 MPa) that can be effectively reduced to 85% of the first maximum stress value.

In the present embodiment, the light-permeable sheet 5 is disposed on the ring-shaped supporting layer 4 through the ring-shaped distribution groove 54, the inner supporting wall 41 of the ring-shaped supporting layer 4 is not in contact with the inner surface 52 of the light-permeable sheet 5, and the inner supporting wall 41 of the ring-shaped supporting layer 4 and the inner side wall 541 of the ring-shaped distribution groove 54 are spaced apart from each other so as to jointly define a ring-shaped gap G therebetween, so that a delamination defect between the light-permeable sheet 5 and the ring-shaped supporting layer 4 can be effectively avoided, and other problems that may occur in the sensor package structure 100 during a manufacturing process (e.g., a bleeding defect of the ring-shaped supporting layer 4 during a curing process; or, a tilt defect or a squash defect of the light-permeable sheet 5) can be further improved upon.

The outer supporting wall 42 is spaced apart from the outer edge 5422 of the ring-shaped slanting wall 542, so that the outer supporting wall 42, the ring-shaped slanting wall 542, and the carrying region 212 of the sensor chip 2 jointly define a ring-shaped fixing groove S. Moreover, a width of the ring-shaped fixing groove S gradually increases in a direction from an opening of the ring-shaped fixing groove S toward the outer supporting wall 42, but the present disclosure is not limited thereto. For example, in other embodiments of the present disclosure not shown in the drawings, the outer supporting wall 42 can be flush with or coplanar with the surrounding lateral surface 53 of the light-permeable sheet 5.

The encapsulant 6 in the present embodiment is formed on the first surface 11 of the substrate 1, and lateral edges of the encapsulant 6 are respectively flush with lateral edges of the substrate 1. The sensor chip 2, the ring-shaped supporting layer 4, the light-permeable sheet 5, and each of the metal wires 5 are embedded in the encapsulant 6, and at least part of the outer surface 51 of the light-permeable sheet 5 is exposed from the encapsulant 6. Moreover, the ring-shaped fixing groove S is fully filled with the encapsulant 6, such that the sensor chip 2, the ring-shaped supporting layer 4, and the light-permeable sheet 5 can be firmly connected to each other through the encapsulant 6.

Specifically, the encapsulant 6 in the present embodiment is a solidified liquid compound, but the present disclosure is not limited thereto. For example, in other embodiments of the present disclosure not shown in the drawings, the encapsulant 6 can include a solidified liquid compound and a molding compound that is formed on a top surface of the solidified liquid compound; or the encapsulant 6 can be a molding compound.

### Second Embodiment

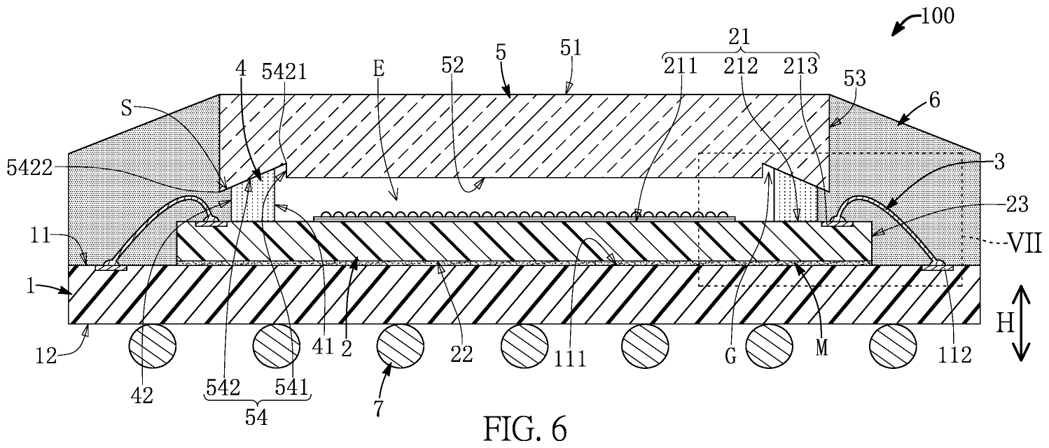

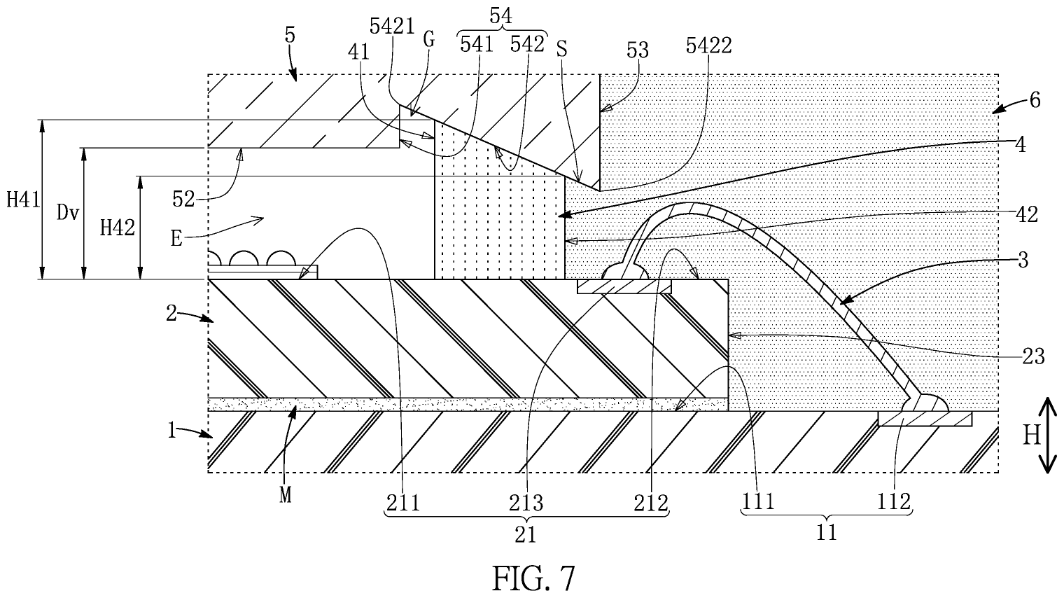

Referring to FIG. 6 and FIG. 7, a second embodiment of the present disclosure, which is similar to the first embodiment of the present disclosure, is provided. For the sake of brevity, descriptions of the same components in the first and second embodiments of the present disclosure will be omitted herein, and the following description only discloses different features between the first and second embodiments.

In the present embodiment, the inner surface 52 of the light-permeable sheet 5 is spaced apart from the sensor chip 2 along the thickness direction H by a vertical distance Dv that can be adjusted according to design requirements. For example, the light-permeable sheet 5 can be thinned from the inner surface 52 for increasing the vertical distance Dv. Specifically, the vertical distance Dv is preferably in cooperation with the height H41 of the inner supporting wall 41 and the height H42 of the outer supporting wall 42. For example, the height H41 of the inner supporting wall 41 is within a range from 110% to 120% of the vertical distance Dv, and the height H42 of the outer supporting wall 42 is within a range from 80% to 90% of the vertical distance Dv.

### Third Embodiment

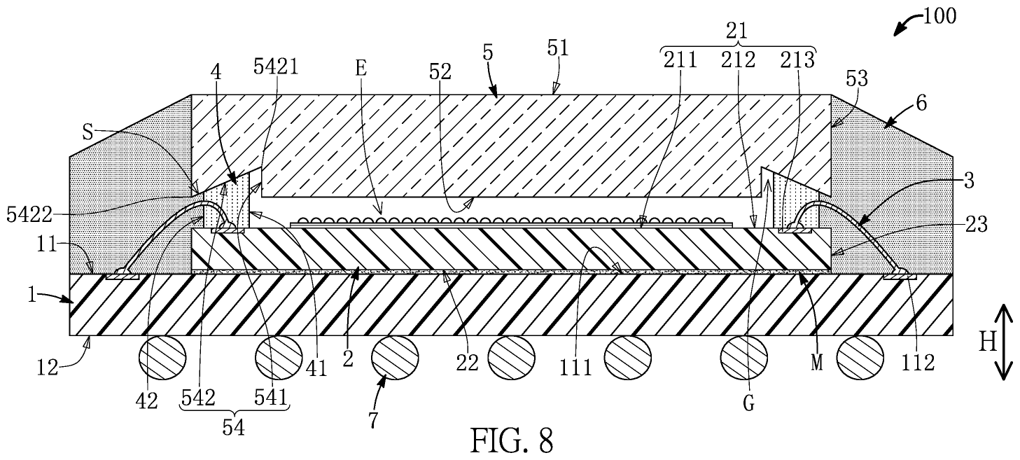

Referring to FIG. 8, a third embodiment of the present disclosure, which is similar to the first embodiment of the present disclosure, is provided. For the sake of brevity, descriptions of the same components in the first and third embodiments of the present disclosure will be omitted herein, and the following description only discloses different features between the first and third embodiments.

In the present embodiment, the ring-shaped supporting layer 4 is disposed on the carrying region 212 of the sensor chip 2 and surrounds the sensing region 211. In other words, the connection pads 213 are embedded in the ring-shaped supporting layer 4, and one of the two ends of each of the metal wires 3 connected to the corresponding connection pad 213 is embedded in the ring-shaped supporting layer 4.

It should be noted that the connection relationship of the light-permeable sheet 5 and other components preferably meets the following features for facilitating the packaging of the sensor chip 2 of a smaller size. The connection pads 213 are located directly under the ring-shaped slanting wall 542 and are embedded in the ring-shaped supporting layer 4, such that at least one of the metal wires 3 can be partially arranged in the ring-shaped distribution groove 54 and is not in contact with the ring-shaped distribution groove 54.

### Beneficial Effects of the Embodiments

In conclusion, the light-permeable sheet of the sensor package structure provided by the present disclosure is formed with the ring-shaped slanting wall that is cooperated with the ring-shaped supporting layer, so that the ring-shaped supporting layer can be shaped to effectively improve a stress concentration in the inner supporting wall, thereby preventing a crack from occurring at the inner supporting wall.

Specifically, the light-permeable sheet of the sensor package structure provided by the present disclosure is disposed on the ring-shaped supporting layer through the ring-shaped distribution groove, so that a delamination defect between the light-permeable sheet and the ring-shaped supporting layer can be effectively avoided, and other problems that may occur in the sensor package structure during a manufacturing process (e.g., a bleeding defect of the ring-shaped supporting layer during a curing process; or, a tilt defect or a squash defect of the light-permeable sheet) can be further improved upon.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A sensor package structure, comprising:
a substrate having a first surface and a second surface that is opposite to the first surface;
a sensor chip disposed on the first surface of the substrate and electrically coupled to the substrate, wherein a top surface of the sensor chip has a sensing region and a carrying region that is arranged outside of the sensing region;
a ring-shaped supporting layer disposed on the carrying region and surrounding the sensing region; and
a light-permeable sheet disposed on the ring-shaped supporting layer, wherein the light-permeable sheet, an inner supporting wall of the ring-shaped supporting layer, and the top surface of the sensor chip jointly define an enclosed space, and wherein the light-permeable sheet has:
an outer surface;
an inner surface being opposite to the outer surface and facing toward the sensing region, wherein the sensing region is located in a projection region defined by orthogonally projecting the inner surface onto the top surface; and
a ring-shaped distribution groove arranged opposite to the outer surface and surrounding the inner surface, wherein the ring-shaped distribution groove has a ring-shaped slanting wall and an inner side wall that is connected in-between the inner surface and an inner edge of the ring-shaped slanting wall;
wherein a top portion of the ring-shaped supporting layer is disposed in the ring-shaped distribution groove and is connected to the ring-shaped slanting wall, such that a height of the inner supporting wall is within a range from 120% to 150% of a height of an outer supporting wall of the ring-shaped supporting layer.

2. The sensor package structure according to claim 1, wherein the light-permeable sheet has a surrounding lateral surface that is connected in-between the outer surface and an outer edge of the ring-shaped slanting wall, and wherein the outer edge of the ring-shaped slanting wall is coplanar with the inner surface of the light-permeable sheet.

3. The sensor package structure according to claim 1, wherein the inner surface of the light-permeable sheet is spaced apart from the sensor chip by a vertical distance, and wherein the height of the inner supporting wall is within a range from 110% to 120% of the vertical distance, and the height of the outer supporting wall is within a range from 80% to 90% of the vertical distance.

4. The sensor package structure according to claim 1, wherein a direction perpendicular to the inner surface is defined as a thickness direction, and wherein the inner side wall of the ring-shaped distribution groove and the thickness direction have a first angle therebetween, and the ring-shaped slanting wall and the thickness direction have a second angle therebetween that is greater than the first angle.

5. The sensor package structure according to claim 1, wherein the inner supporting wall of the ring-shaped supporting layer is not in contact with the inner surface of the light-permeable sheet, and the inner supporting wall of the ring-shaped supporting layer and the inner side wall of the ring-shaped distribution groove are spaced apart from each other so as to jointly define a ring-shaped gap therebetween.

6. The sensor package structure according to claim 1, further comprising an encapsulant formed on the first surface of the substrate, wherein the sensor chip, the ring-shaped supporting layer, and the light-permeable sheet are embedded in the encapsulant, and at least part of the outer surface of the light-permeable sheet is exposed from the encapsulant.

7. The sensor package structure according to claim 6, wherein the outer supporting wall is spaced apart from an outer edge of the ring-shaped slanting wall, so that the outer supporting wall, the ring-shaped slanting wall, and the carrying region of the sensor chip jointly define a ring-shaped fixing groove, and wherein the ring-shaped fixing groove is fully filled with the encapsulant, and a width of the ring-shaped fixing groove gradually increases in a direction from an opening of the ring-shaped fixing groove toward the outer supporting wall.

8. The sensor package structure according to claim 1, wherein the substrate includes a plurality of bonding pads that are arranged on the first surface and that are located outside of the sensor chip, and the sensor chip includes a plurality of connection pads that are arranged on the carrying region and that are located outside of the ring-shaped supporting layer, and wherein the sensor package structure includes a plurality of metal wires each having two ends that are respectively connected to one of the bonding pads and one of the connection pads.

9. The sensor package structure according to claim 1, wherein the substrate includes a plurality of bonding pads that are arranged on the first surface and that are located outside of the sensor chip, and the sensor chip includes a plurality of connection pads that are arranged on the carrying region, and the connection pads are located directly under the ring-shaped slanting wall and are embedded in the ring-shaped supporting layer, and wherein the sensor package structure includes a plurality of metal wires each having two ends, and one of the two ends of each of the metal wires is connected to one of the bonding pads, and another one of the two ends of each of the metal wires is connected to one of the connection pads and is embedded in the ring-shaped supporting layer.

10. The sensor package structure according to claim 1, wherein the height of the inner supporting wall is within a range from 130% to 140% of the height of the outer supporting wall.
